(19) United States
(12) Patent Application Publication
(10) Pub. No.: US 2021/0341651 A1
(43) Pub. Date: Nov. 4, 2021

(54) ANGLED SOLAR REFRACTING SURFACE

(71) Applicant: Mun Chew Kong, Singapore (SG)

(72) Inventor: Stephen D. Newman, Bayshore Park (SG)

(21) Appl. No.: 17/261,158

(22) PCT Filed: Jul. 18, 2019
(86) PCT No.: PCT/SG2019/050348

§ 371 Date: Jan. 18, 2021

(30) Foreign Application Priority Data
Jul. 18, 2018 (SG) 10201806159P

(51) Int. Cl. G02B 3/08; F24S 23/30; F24S 10/70; F24S 20/30

(52) U.S. Cl. CPC G02B 3/08; F24S 20/30; F24S 10/70; F24S 23/31

(57) ABSTRACT

A concentrator apparatus can include a light receiver and a light concentrator. The light concentrator can include a first concentrating lens with a first focal point on the light receiver. A first side of the first concentrating lens can be closer to the first focal point than a second side of the first concentrating lens.

### BACKGROUND

A solar concentrator uses lenses, often Fresnel lenses, to focus a large area of sunlight towards a specific focal spot. This is done by bending the rays of light that pass through the Fresnel lens so that each of the light rays is directed to approximately the same focal point. Some Fresnel lenses are shaped with concentric rings of prisms that focus the light rays. These features cause the Fresnel lens to focus scattered light from the sun or other source into a tight beam. The concentration of solar power increases the temperature at the focal point, which can be used to heat objects or cook food. In other examples, the Fresnel lens can be used to increase the light on a solar cell to increase the amount of light that is converted into electricity.

An example of a Fresnel lens is disclosed in U.S. Pat. No. 9,097,841 issued to Luigi Salvatore Fornari. In this reference, a Fresnel lens array is provided in which the vertical part of a lens element is replaced by a tilted surface designed to focus impinging light into the focal point of an adjacent lens in the array. Since the new surface forms an angle with the lens plane that is shallower than the vertical step, such a lens element configuration can ease the molding of the lens array in glass type materials. The configuration is not limited to cylindrical arrays, since another array with lens elements perpendicular to the first lens array can be molded on the other side of the lens sheet, resulting in an array of point focusing lenses. Furthermore, by placing mirrors at the edges of the lens array (or at the edge of a single lens thereof) with surfaces perpendicular to the lens plane, the edge light rays can be redirected back to the focal point(s). In particular, single circular lenses, with lens element cross-sections similar to the one described above and with a vertical mirror at the edge, will also concentrate collimated light to the focal point.

Another example of a Fresnel lens is disclosed in U.S. Pat. No. 5,410,563 issued to Hiromu Nakamura. In this reference, a laser beam light source device is disclosed which has a Fresnel lens having grating of unequal spacing and facing a laser diode, and condenser lens made of resin. The focal length of the condenser lens is set at a value which nullifies changes in the focal length of the Fresnel lens induced by fluctuations in the oscillation wavelength of the laser diode accompanying temperature change, and changes in the focal length of the Fresnel lens accompanying temperature change. Further, a laser beam scanning optical system for scanning on a scan line via a deflecting device and optical elements by a laser beam emitted from a laser light source based on image information are disclosed. In the laser scanning optical system, a pair of anamorphic lenses are disposed anteriorly and posteriorly to the deflecting device to correct surface tilt of the deflecting device, one of the anamorphic lens being a Fresnel lens, another of the anamorphic lenses being made of resin.

Yet another example of a Fresnel lens is disclosed in U.S. Patent Publication No. 20160265740 issued to Silvia Booij. In this reference, an optical beam shaping arrangement is disclosed. In one example, the optical beam shaping arrangement includes a collimator for receiving light from an optical source, and providing a more collimated output, and an optical plate for receiving the more collimated output, the optical plate including a two dimensional array of lenses on an input side and a corresponding two dimensional array of lenses on the opposite output side. In at least one embodiment, the lenses on the input side each have a focal point at a corresponding lens on the output side, and the lenses on the output side each have a focal point at a corresponding lens on the input side, and at least some of the lenses on the output side are tilted with respect to the general plane of the optical plate. All of these references are herein incorporated by reference for all that they disclose.

### SUMMARY

In one embodiment, a concentrating lens includes a transparent material. The transparent material includes a light receiving surface of the transparent material, a light exiting surface of the transparent material opposite the light receiving surface, a plurality of refractive surfaces of the transparent material incorporated into at least one of the light receiving surface and the light exiting surface, a first side joining the light receiving surface and the light exiting surface and a second side opposite to and aligned with the first side, the second side joining the light receiving surface and the light exiting surface. The plurality of refractive surfaces directs light passing through the transparent material to a collective focal point, and the first side of the transparent material is closer to the collective focal point than the second side of the transparent material.

The transparent material can be at least semi-transparent.

The concentrating lens can include a neutral refractive surface of the refractive surfaces that causes light perpendicular to the light receiving side to maintain an un-refracted course towards collective focal point.

At least a subset of the plurality of refractive surfaces can include progressively differing refractive angles towards the neutral refractive surface.

The refractive surfaces can be concentric.

The refractive surfaces can be aligned with at least one of a first side and the second side of the transparent material.

In one embodiment, a concentrator apparatus can include a light receiver and a light concentrator. The light concentrator can include a first concentrating lens with a first focal point on the light receiver. A first side of the first concentrating lens can be closer to the first focal point than a second side of the first concentrating lens.

The concentrator apparatus can include a partial vacuum space between the light concentrator and the light receiver.

The light receiver can include an insulating section that is configured to retain heat within the light receiver.

The light receiver can be a solar panel.

The light receiver can be an article of clothing.

The light receiver can be a building component.

The light receiver can be a cooking apparatus.

The light receiver can be a fluid receptacle.

The light receiver can be a pipe.

The pipe can be configured to carry a fluid.

The pipe can include a vacuum section.

The pipe can include an insulation layer configured to retain heat within the pipe.

The concentrator apparatus can include a heat exchanger incorporated into the insulation layer.

The concentrator apparatus can include a heat spreader incorporated into the light receiver.

The concentrator apparatus can include a second concentrating lens adjacent to the first concentrating lens. The first concentrating lens can be offset from the second concentrating lens, and the second concentrating lens can have a second focal point on the light receiver.

The first focal point and the second focal point can be on different locations of the light receiver.

The first focal point and the second focal point can be at a same location on the light receiver.

The second concentrating lens can have a first side closer to the second focal point than a second side of the concentrating lens.

In one embodiment, a concentrator apparatus can include a light receiver and a light concentrator, the light concentrator can include a first concentrating lens with a first focal point on the light receiver. A first side of the first concentrating lens can be closer to the focal point than a second side of the concentrating lens. A second concentrating lens can be adjacent to the first concentrating lens. The second concentrating lens can have a second focal point on the light receiver.

The first focal point and the second focal point can be on different locations of the light receiver.

The first focal point and the second focal point can be at a same location on the light receiver.

The second concentrating lens can have a first side closer to the second focal point than a second side of the concentrating lens.

In one embodiment, a concentrator apparatus includes a light receiver and a light concentrator. The light concentrator can include a first concentrating lens with a first focal point on the light receiver. The first concentrating lens is configured to direct light to a first focal point and is asymmetrically positioned over the first focal point.

The concentrator apparatus can include a partial vacuum space between the light concentrator and the light receiver.

The light receiver can include an insulating section that is configured to retain heat within the light receiver.

The light receiver can be a solar panel.

The light receiver can be a pipe.

The pipe can include an insulation section configured to retain heat within the pipe.

The concentrator apparatus can include a second concentrating lens adjacent to the first concentrating lens. The second concentrating lens can be configured to direct light to a second focal point and can be asymmetrically positioned over the second focal point on the light receiver.

In one embodiment, a concentrator apparatus can include a light concentrator. The light concentrator can include a first concentrating lens with a first focal point. A first side of the first concentrating lens is closer to the first focal point than a second side of the first concentrating lens.

The concentrator apparatus can include a light receiver. The focal point can be on the light receiver.

The concentrator apparatus can include a second light concentrator. The second light concentrator can include a second concentrating lens with a second focal point.

The first side of the second concentrating lens can be closer to the second focal point than a second side of the second concentrating lens.

The second focal point can be on the light receiver.

The first focal point and the second focal point can be spaced apart at a distance.

In one embodiment, a concentrating lens can include a transparent material. The transparent material can include a light receiving surface of the transparent material and a light exiting surface of the transparent material opposite the light receiving surface. The area between the light receiving surface and the light exiting surface defining at least one concentrating plane. The at least one concentrating plane can contain a midpoint. The concentrating lens can also include a plurality of refractive surfaces of the transparent material incorporated into at least one of the light receiving surface and the light exiting surface. The plurality of refractive surfaces can direct light passing through the transparent material to a collective focal point. A focal axis from the collective focal point to the midpoint can form a non-right angle with the concentrating plane.

The non-right angle can be between 60 degrees and 89 degrees.

In one embodiment, a concentrator apparatus includes a light receiver and a light concentrator. The light concentrator can include a first transparent material, a first concentrating lens with a first focal point on the light receiver, and a second transparent material between the first transparent material and the first concentrating lens. The first concentrating lens is configured to direct light to the first focal point and is asymmetrically positioned over the first focal point.

The second transparent material can be a fluid, such as an oil including, but in no way limited to, Cargille optical oils (calibration liquids, immersion liquids, optical gels, or designer oils having tuned refractive indexes).

The concentrator apparatus can include a pathway defined in the light receiver configured to accommodate a flow of fluid.

The pathway can include a first portion defined in the light receiver and a second portion defined in part by the first light transparent material and the first light concentrating lens.

The second transparent material can be configured to flow through the pathway.

The concentrator apparatus can exhibit a solar heat transfer to the second transparent material when the second transparent material is located the first portion of the pathway.

The concentrator apparatus can exhibit a solar heat transfer to the second transparent material when the second transparent material is located the second portion of the pathway.

The concentrator apparatus can include a first characteristic of exhibiting a first solar heat transfer to the second transparent material when the second transparent material is located in the first portion of the pathway and a second characteristic of exhibiting a second solar heat transfer to the second transparent material when the second transparent material is located in the second portion of the pathway. The first heat transfer can exhibit a greater temperature increase than the second solar heat transfer.

The concentrator can include surfaces having meta-optics formed thereon to selectively focus received light.

The concentrator can include a protective coating such as an aliphatic coating. The concentrator can assume any size.

### BRIEF DESCRIPTION OF THE DRAWINGS

The accompanying drawings illustrate various embodiments of the present apparatus and are a part of the specification. The illustrated embodiments are merely examples of the present apparatus and do not limit the scope thereof.

FIG. 1 illustrates a top view of a prior art Fresnel lens.

FIG. 2 illustrates a side view of an example of a concentrating lens in accordance with the present disclosure.

FIG. 3 illustrates a side view of an example of a concentrating apparatus in accordance with the present disclosure.

FIG. 4 illustrates a side view of an example of a concentrating apparatus in accordance with the present disclosure.

FIG. 5 illustrates a side view of an example of a concentrating apparatus in accordance with the present disclosure.

FIG. 6 illustrates a side view of an example of a concentrating lens in accordance with the present disclosure.

FIG. 7 illustrates a side view of an example of a concentrating lens apparatus in accordance with the present disclosure.

FIG. 8 illustrates an example scanning electron microscopic image of a surface having meta-optics formed thereon.

Throughout the drawings, identical reference numbers designate similar, but not necessarily identical, elements.

### DETAILED DESCRIPTION

For purposes of this disclosure, the term “aligned” means parallel, substantially parallel, or forming an angle of less than 35.0 degrees. For purposes of this disclosure, the term “transverse” means perpendicular, substantially perpendicular, or forming an angle between 55.0 and 125.0 degrees. Also, for purposes of this disclosure, the term “length” means the longest dimension of an object. Also, for purposes of this disclosure, the term “width” means the dimension of an object from side to side. Often, the width of an object is transverse the object's length. For purposes of this specification, a concentrating plane generally refers to a plane at which rays parallel to the axis are deviated to converge to a focal point. For purposes of this specification, a focal axis is an axis the passes through a mid-point of a concentrating plane and a collective focal point.

Fresnel lenses are used in solar collectors to concentrate light through refraction. Conventional Fresnel lenses approximate a curved lens, but with less material. Thus, a Fresnel lens weighs less than a corresponding curved lens. In some cases, the Fresnel lens focuses parallel rays of light to a focal point. Generally, a Fresnel lens includes a flat side and a canted side. The canted side includes canted facets that form refractive surfaces, which approximate the curvature of a lens. Typically, the more facets, the better the approximation of the curved lens.

Generally, all the light that passes through the Fresnel lens is concentrated to a single point. Thus, the larger the surface area of the Fresnel lens, the more light is concentrated to the single point. A Fresnel lens with a greater surface area will often have a longer focal length because the light rays passing through the sides of the Fresnel lens will be focused to the same focal point that light rays passing through the central portion of the Fresnel lens pass, but the light rays passing through the sides have to travel a longer distance than the light rays passing through the center. Thus, as a general rule, the larger the surface area of the Fresnel lenses, the longer the focal length to the focal point. This is due, in part, to the symmetry of the Fresnel lens. Based on this general rule, as the surface area increases, the Fresnel lens is placed at a farther distance from the focal point, taking up more space.

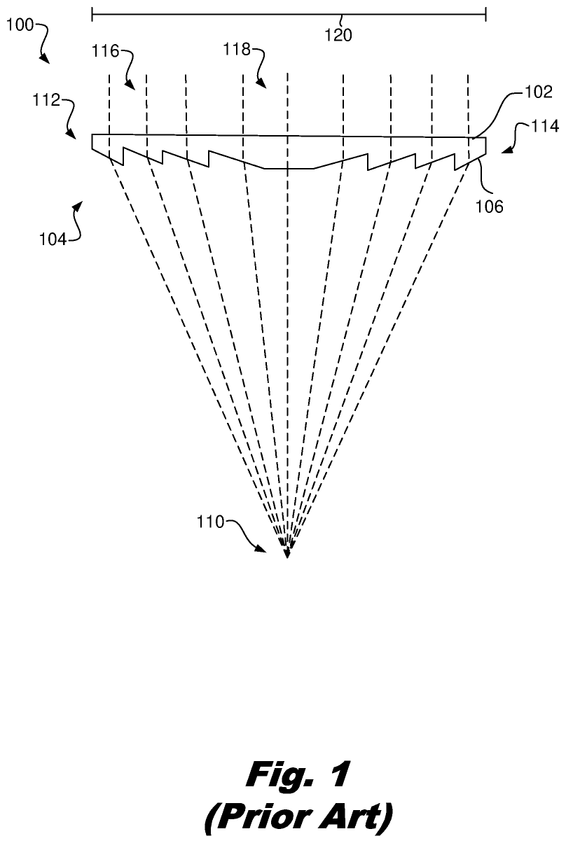

FIG. 1 depicts a prior art example of a Fresnel lens 100. Here, the Fresnel lens 100 includes a light receiving surface 102 that is generally flat. A light exit side 104 of the Fresnel lens 100 is opposite to, and aligned with, the light receiving surface 102. The light exit surface 104 includes a plurality of canted faces 106 that form refractive surfaces. Light that is generally perpendicular to the flat light receiving surface 102 enters the light receiving surface without a substantial refraction, if any. The refractive surfaces on the light exiting surface 104 refract the light towards a focal point 110. The Fresnel lens 100 is generally symmetric with a first side 112 and a second side 114 of the lens, substantially equidistant to the focal point 110. The refracted light transmitted through the side regions 116 of the Fresnel lens have a farther distance to travel to the focal point 110 than the unrefracted light at a central region 118 of the Fresnel lens 110.

The surface area of the Fresnel lens 100 is determined by the length and width of the Fresnel lens 100. In this depiction of the prior art Fresnel lens, just the width 120 of the Fresnel lens 100 is depicted.

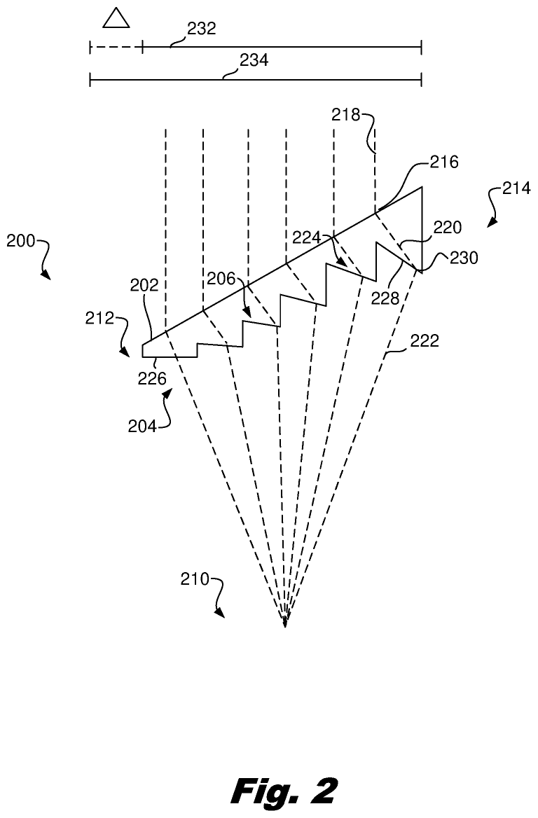

FIG. 2 depicts an embodiment of a light concentrating lens 200. In some examples, the light concentrating lens is a Fresnel lens, but the principles depicted in FIG. 2 can be applied to other types of light concentrating lens.

The light concentrating lens 200 includes a light receiving surface 202 and a light exiting surface 204. The light receiving surface 202 is generally flat, and the light exiting surface 204 includes a plurality of canted faces 206, which form refractive surfaces that affect the direction of the light rays exiting the lens 200. Each of the refractive surfaces are focused on directing the light to a single focal point 210.

A first side 212 of the light concentrating lens 200 connects the light receiving surface 202 with the light exiting surface 204. A second side 214 of the light concentrating lens 200 is opposite to the first side 212 and connects the light receiving surface 202 with the light exiting surface 204. In this example, the first side 212 is closer to the focal point 210 than the second side 214. In this example, the light concentrating lens 200 has a substantially flat light receiving surface 202; thus, the concentrating lens 200 is tilted at an angle. Further, the first side 212 is located at a greater vertical distance or elevation away from the focal point than the second side 214 of the light concentrating lens 200.

The light concentrating lens 200 can be tilted to any appropriate angle relative to horizontal. For example, the light concentrating lens 200 can be tilted to an angle of at least 5 degrees, of at least 10 degrees, of at least 15 degrees, of at least 20 degrees, of at least 25 degrees, of at least 30 degrees, of at least 35 degrees, of at least 40 degrees, of at least 45 degrees, of at least 50 degrees, of at least 55 degrees, of at least 60 degrees, of at least 65 degrees, of at least 70 degrees, of at least 75 degrees, of at least 80 degrees, of at least 85 degrees, or at least another appropriate angle, or combinations thereof.

The light concentrating lens 200 can be formed of a material that is at least partially transparent. In some examples, the material of the light concentrating lens 200 can have the characteristic of having at least 20 percent total transmittance, at least 30 percent total transmittance, at least 40 percent total transmittance, at least 50 percent total transmittance, at least 60 percent total transmittance, at least 70 percent total transmittance, at least 80 percent total transmittance, at least 85 percent total transmittance, at least 90 percent total transmittance, at least 95 percent total transmittance, another appropriate total transmittance, or combinations thereof. In some examples, the light concentrating material can be a glass, a plastic, a resin, diamond, sapphire, ceramics, another type of material, or combinations thereof.

As the light enters the receiving surface 202, the light can be refracted when the entering or received light is not perpendicular to the light receiving surface 204. In this case, the substantially parallel light rays that are generally traveling towards, but not focused on the focal point, can be refracted due to the relative angle between the incoming light and the light receiving surface 202. This refraction that occurs at the light receiving surface 202 can be a first refractive angle 216 of a light ray that bends a natural light ray 218 into a partially refracted light ray 220. The relative angle of the canted face 206 with the partially refracted light ray 220 can cause the partially refracted light ray 220 to bend into a focused light ray 222 on the focal point. Thus, the light can be refracted at multiple points while still traveling in the general direction towards the focal point.

For those light rays entering the flat light receiving surface 202 that are generally parallel, the light is refracted at the same angle to form the partially refracted light rays. The partially refractive light rays travel through and are contained within the transparent material. The partially refractive light rays are refracted into focused light rays directed to the focal point as these partially refractive light rays exit the transparent material. The transition from the partially refractive light rays to the focused light rays forms a second refractive angle 224. The second refractive angle 224 can be formed based on the angle of the canted face on the light exiting surface of the transparent material. From the first side of the light transparent material to the second side of the light transparent material, the canted faces can progressively increase in angle to focus each of the light rays along the concentrating lens' length to the focal point. Thus, the refractive angles can be different based upon the location of the light ray with respect to the concentrating lens' cross sectional length. For some canted faces 206 the second refractive angle 224 can be generally perpendicular to the partially refracted light ray 220 resulting in only a minor refraction to form the focused light ray 222. However, in other portions of the light exiting surface 204, the relative angle between the canted faces 206 and the partially refractive light ray 220 can be an acute angle or an obtuse angle to force a greater refractive correction to form the focused light ray 222. Additionally, the relative angle of the canted faces 206 can be tuned relative to an overall desired angular position of the light receiving surface 202 relative to horizontal to direct received light to a desired focal point 210.

In the depicted example, the first canted face 226 proximate the first side 212 of the concentrating lens 200 provides a minor refractive adjustment to form the focused light ray 222. Each of the canted faces 206 from the first side 212 in the direction to the second side 214 progressively form a more pronounced angle that causes a greater angle change between the partially refracted light ray 220 and the focused light ray 222. For example, the farthest most canted face 228 proximate the second side 214 of the concentrating lens 200 can form a steep acute angle 230 with the partially refracted light ray 220 resulting in a greater second refractive angle 224. In some examples, the canted face proximate the first side of the concentrating lens has a different refractive surface angle than the canted face of the second side of the concentrating lens, but each of these canted faces directs the focused light rays to the same focal point 210.

The first refractive angle 216 can be any appropriate angle. For example, a non-exhaustive list of angles that can be compatible for the first refractive angle can include angles less than 90 degrees, less than 60 degrees, less than 50 degrees, less than 45 degrees, less than 40 degrees, less than 35 degrees, less than 30 degrees, less than 25 degrees, less than 20 degrees, less than 15 degrees, less than 10 degrees, less than 5 degrees, or less than another appropriate angle.

The second refractive angle 224 of any of the individual canted faces can be any appropriate angle. For example, a non-exhaustive list of angles that can be compatible for the canted faces' refractive angles can include angles less than 90 degrees, less than 60 degrees, less than 50 degrees, less than 45 degrees, less than 40 degrees, less than 35 degrees, less than 30 degrees, less than 25 degrees, less than 20 degrees, less than 15 degrees, less than 10 degrees, less than 5 degrees, or less than another appropriate angle.

The second refractive angle 224 can be affected by the first refractive angle 216 and the relative lateral distance each of the canted faces 206 is expected to be with respect to the focal point. For example, many of the canted faces can form a negative angle between the partially refracted light ray 220 and the focused light ray 222. On the other hand, other canted faces can be oriented to form a positive angle between the partially refracted light ray 220 and the focused light ray 222.

In the depicted example, the first side 212 of the concentrating lens 200 is closer to the focal point 210 than the second side 214 of the concentrating lens 200. As a result, the concentrating lens 200 is offset or asymmetrically oriented about the focal point. Thus, each of the canted faces 206 are angled to asymmetrically focus each of the light rays to an off-centered focal point 210.

One advantage to having the concentrating lens 200 orientated at an angle relative to the focal point is that more concentrating lenses with the same surface area can be fit into the same footprint. For example, the angled concentrating lenses can increase the overall surface area that can be used to concentrate light because additional concentrating lenses can be included within the same footprint. With an increased surface area, more light can be concentrated in a smaller area, thereby enhancing the thermal efficiency of the lens.

In FIG. 2, line 232 represents the width of the concentrating lens 200 compared to the width of the Fresnel lenses depicted in FIG. 1 represented by line 234. As can be seen, line 234 is shorter than 232, resulting in a net width difference delta (A). This additional space can be used to provide an additional concentrating lens. For example, if the tilted concentrating lens resulted in a 20 percent space reduction that provided the same amount of concentrated light, a fifth concentrating lens could be fit into a footprint where only four concentrating lens would have previously fit.

In the example of FIG. 2, the light exiting surface 204 includes the canted faces 206 and the light receiving side 202 is generally flat. However, in alternative examples, the light exiting surface can be generally flat and the light receiving side can include the canted faces. In yet other alternative examples, each of the light receiving surface and the light exiting surfaces can include a mix of canted faces and generally flat regions.

FIG. 3 depicts an example of a light concentrating apparatus 300. In this example, the concentrator apparatus 300 includes a light receiver 302 and a light concentrator 304 with multiple light concentrating lenses. For purpose of clarity, the specific lens geometric details of each concentrating lens are not shown in FIG. 3. The light concentrator 304 includes a first concentrating lens 306 with a first focal point 308 on the light receiver 302. A first side 310 of the first concentrating lens 306 is closer to the first focal point 308 than a second side 312 of the first concentrating lens 306. Thus, the first light concentrating lens 306 is offset and focuses the light rays to an off-centered focal point. With the first light concentrating lens 306 being asymmetrically positioned around the first focal point 308, the first light concentrating lens' footprint is smaller than a traditional Fresnel lens that would be symmetrically oriented about the focal point.

The light concentrating apparatus 300 also includes a second light concentrating lens 314. In this example, the second light concentrating lens 314 is also asymmetrically oriented about a second focal point 316. Thus, a first side 318 of the second light concentrating lens 314 is closer to the second focal point 316 than a second side 320 of the light concentrating lens 314. In this example, the second light concentrating lens 314 is transversely oriented with respect to the first light concentrating lens 306. Thus, the first and second light concentrating lenses 306, 314 form a non-180 degree angle.

The angle formed between the first and second light concentrating lenses 306, 314 can be any appropriate angle. In some examples, the angle is greater than 5 degrees, greater than 10 degrees, greater than 15 degrees, greater than 20 degrees, greater than 25 degrees, greater than 30 degrees, greater than 40 degrees, greater than 45 degrees, greater than 50 degrees, greater than 60 degrees, greater than 70 degrees, greater than 80 degrees, greater than 90 degrees, greater than 100 degrees, greater than 105 degrees, greater than 110 degrees, greater than 120 degrees, greater than 130 degrees, greater than 140 degrees, greater than 150 degrees, greater than 160 degrees, greater than 170 degrees, greater than another appropriate degree, or combinations thereof.

In the example depicted in FIG. 3, the first focal point 308 and the second focal point 316 are spaced apart from one another at a distance. The first and second focal points 308, 316 can be spaced apart at any appropriate distance. In some examples, the first and second focal points 306, 316 are spaced apart at a distance of less than 1.0 inch, less than 2.0 inches, less than 3 inches, less than 5 inches, less than 7 inches, less than 10 inches, less than 15 inches, less than 20 inches, less than 25 inches, less than another appropriate distance, or combinations thereof. In some examples, the first and second light concentrating lenses 306, 314 focus light at the exact same point on the light receiver 302.

In those examples where both the first and second light concentrating lenses 306, 314 are offset, the footprint reduction of the tilted lenses is additive. Thus, the benefit of a greater amount of light can be concentrated to the light receiver 302 in a smaller area. Additional light concentrating lenses can be added to the freed space available around the light receiver 302, which increases the overall amount of light concentrated to the light receiver 302.

In the depicted example, a plurality of light concentrating lenses forms a zig-zig cross section. While the example in FIG. 3 depicts each of the light concentrating lenses oriented to form a symmetrical cross section, at least one of the light concentrating lenses can be oriented such that it is orientated at a different offset angle than at least two other lenses in the plurality of light concentrating lenses. Further, while the example in FIG. 3 depicts each of the concentrating lenses having the same length or dimensions, in alternative examples, at least one of the concentrating lens has a different length than at least one of the other concentrating lenses.

The light receiver 302 can be any appropriate object or fluid. In one example, the light receiver 302 is a solar cell that converts light energy into electrical energy. By focusing more light on the solar cell within an area, the solar cell can convert more electricity in the same area. Thus, the productivity of the solar cell can be increased without increasing the foot print of the solar cell and/or the concentrating apparatus. In those examples, where the concentrating apparatus is part of a solar farm, the solar farm can be more productive without increasing the solar farm's footprint.

In another example, the light receiver 302 can be pipe or another type of conduit that can hold and/or carry a gas or a fluid. In some examples, the fluid is a gas. In other examples, the fluid is a water-based liquid and/or an oil based liquid. Individual homes, buildings, or communities can use the light concentrator apparatus to heat water. Such heated water can be used to run showers, dishwashers, washing machines, or other home-based or industry-based applications. In yet other examples, the water can be converted into steam which can be used to power a turbine for electricity generation. In yet another example, the heated water can be used in a heat exchanger that can be used to heat or cool a building, generate electricity, heat a pool, heat sidewalks, heat driveways or roads, regulate a climate within a building, heat other objects, regulate the temperature of other objects, or combinations thereof.

In another embodiment, the light receiver 302 can be any article there a transfer of thermal energy is desired. For example, the light receiver can be an article of clothing; a building element such as a roof, window, or wall; a tent surface; an automobile surface; a boat surface; or any other structural element. Additionally, the light concentrator apparatus can assume any appropriate size to effectively and efficiently transfer thermal energy to the desired article. In one embodiment, the light concentrator apparatus includes a plurality or an array of light concentrator lenses. The light concentrator lenses may be a micro array of lenses that can be incorporated into any environment, including clothing.

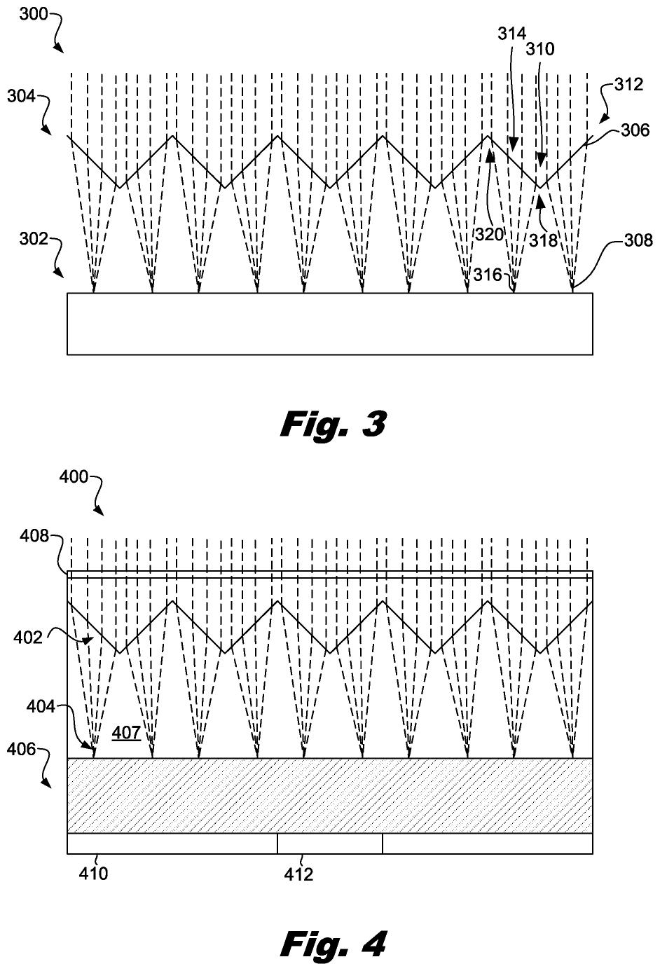

FIG. 4 depicts an example of a light concentrator apparatus 400. In this example, the light concentrator apparatus 400 includes concentrating lenses 402 that alternate with offset angles with respect to each other. In this example, each of the offset alternating lenses 402 directs light to offset focal points 404 on a light receiver 406. However, in alternative examples, the concentrating lenses 402 can direct at least two of the focal points to the same location.

In the depicted example, the space between the light concentrating lenses 402 and the light receiver 406 is enclosed. In some examples, this enclosed space 407 is filled with an inert or other gas that controls the light transmitting environment. In these examples, the enclosure can prevent dust, debris, or other optical interfering particles from lowering the efficiency of the light transmission from the light concentrating lenses 402 to the light receiver 406. While this example has been described with an enclosure, in alternative embodiments, the light concentrating apparatus does not include an enclosure and air or other gases can pass through the space between the light concentrating lenses and the light receiver.

In another example, the space between the light concentrating lenses 402 to the light receiver 406 can be under a partial vacuum. In this example, the partial vacuum can maintain an environment that is unimpeded as much as possible from gas molecules that could interfere with the transmission of light or at least has that amount of gas reduced from that of ambient conditions. Light travels faster through a vacuum than light travels through a solid, liquid, or gaseous transparent media. This slowing down of light through transparent media is a form of energy transport and involves the absorption and reemission of the light energy by the atoms of the substance. Some of the energy of the light is lost in the absorption and reemission through the transparent substance's molecules. In some cases, this energy loss can be evidenced by a temperature rise in the transparent material.

A complete vacuum can be difficult to achieve on earth's surface. Thus, in some cases, a partial vacuum can be used. To create at least a partial vacuum, the air in the enclosure formed at least in part by the concentrating lenses and the light receiver can be removed with a vacuum pump to achieve a reduced pressure environment, less than environmental pressure, and in one example, less than 1 atm. The enclosure can be made of any appropriate type of material. A non-exhaustive list of materials that can be used include stainless steel, aluminum, mild steel, brass, high density ceramics, glass, acrylic, other types of materials, or combinations thereof.

The light concentrator apparatus 400 can also include a protective transparent barrier 408 that protects the light concentrating lenses 402 from debris or other at least partially opaque materials that could lower the light concentrating lenses transparency. According to one embodiment, the protective transparent barrier 408 can be included on any of the systems disclosed herein, and can include a coating that adds chemical resistance, flexibility, weather, and UV stability. In one embodiment, the transparent barrier is an aliphatic coating, more specifically, an aliphatic urethane coating or an aliphatic polyurethane coating. This coating can increase weathering performance of the surface of the light concentrator apparatus 400, and prevent haze or other obscuring elements that can reduce the efficiency and light transmissibility of the light concentrator apparatus. Light can pass through the protective transparent barrier 408 with or without a refractive change. While the example depicted in FIG. 4 is a substantially flat barrier, the barrier can include any appropriate shape or orientation.

In the illustrated example, the light receiver 406 can also be a pipe that carries a dynamic or stationary fluid. In some cases, the light receiver 406 can be a material with a high heat capacity that retains heat. In those examples where the light receiver 406 transfers heat to a flowing dynamic fluid, the fluid can be heated as it travels through the interior of the pipe. The heated fluid can be used for a useful application after exiting the light receiver 406. In some cases, the light receiver is a porous material through which fluid can be passed. The porous material can increase the surface area that the fluid has with the fluid to improve the thermal transfer. In yet other embodiments, the light receiver 406 includes multiple pipes and/or multiple fluid flow paths within the light receiver 406 to increase the thermal transfer.

The light receiver 406 can be any appropriate color. In some examples, the light receiver 406 includes a black or at least a dark surface to absorb the light. Alternatively, the light receiver 406 can be transparent to allow all of the thermal energy focused by the light concentrating lenses to be passed to the fluid contained therein.

A heat spreader can be incorporated into the light receiver 406. The heat spreader can be made of a thermally conductive material such that hot spots on the light receiver 406 are minimized. Generally, the temperature of the entire heat spreader is relatively uniform since the heat can be spread throughout the entire material. In some cases, the heat spreader is made of a metal or a thermally conductive ceramic. In yet other examples, the entire light receiver 406 is made of a thermally conductive material that minimizes the hot spots by spreading the thermal energy from the focal points throughout the light receiver's material.

An insulation layer 410 can surround the light receiver to trap heat in the light receiver 402. The insulation layer 410 can be made of any appropriate material and have any appropriate thickness. In some cases, the insulation layer includes a reflective surface to further deflect the heat back into the light receiver 406.

In some cases, a heat exchanges 412 and/or absorber can be incorporated into the insulation layer 410. The heat exchanger 412 can be used to transfer the heat in the light receiver 406 to a productive application. In some examples, the heat exchangers 412 are conductive heat exchangers that transfer heat through conduction. These types of heat exchangers can be metal incorporated into the insulation layer 410. In other examples, the heat exchanges can transfer heat through convection.

While the depicted examples have been described with reference to a single light receiver, the light concentrating lenses can project focal points onto multiple light receivers within the light concentrating apparatus.

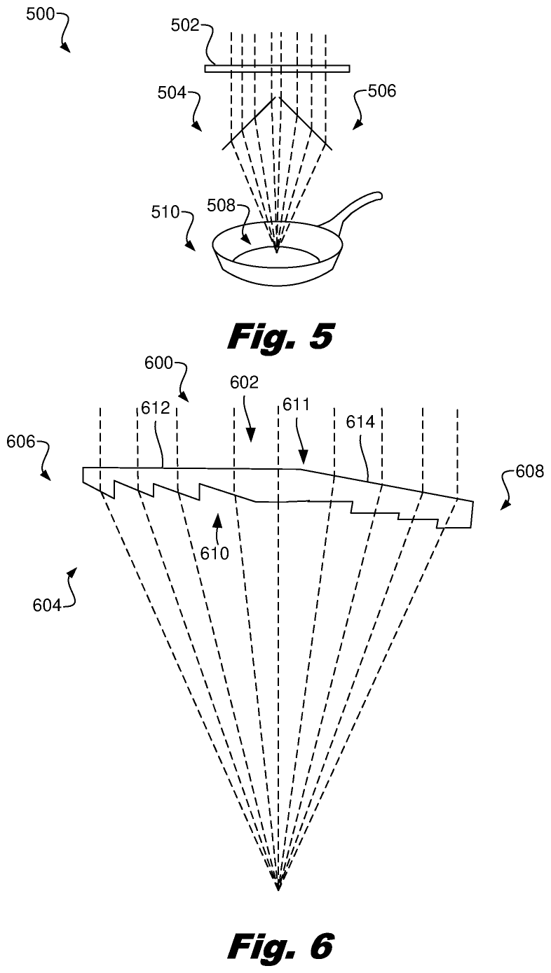

FIG. 5 depicts an example of a light concentrating apparatus 500 having a transparent protective barrier 502 over a first light concentrating lens 504 and a second light concentrating lens 506. Each of the first and second light concentrating lenses 504, 506 direct their respective focal points to the same location 508 on a light receiver 510. In this example, the light receiver 510 is a cooking pan. The heat from the light can be used to cook food in the cooking pan. In this example, there is no closed off enclosure between the light concentrating lenses 504, 506 and the light receiver 510.

FIG. 6 depicts an alternative example of a light concentrating lens 600. In this example, the light concentrating lens 600 includes a light receiving surface 602 and a light exiting surface 604. A first side 606 of the light concentrating lens 600 connects the light receiving surface 602 and the light exiting surface 604. A second side 608 of the light concentrating lens 600 is opposite the first side and also connects the light receiving surface 602 and the light exiting surface 604. The light exiting surface 604 includes canted faces 610 that form refractive surfaces.

The light receiving surface 602 includes a bend 611 separating a first flat surface 612 and a second flat surface 614 that are contiguous, but still a single piece of material. The first flat surface 612 defines in part a first focal plane, and the second flat surface 614 defines in part a second focal plane. The bend 611 forms an angle. As a result, as parallel light rays enter the light receiving surface 602, the light rays entering the first flat surface 612 experience a different refractive change than the light rays entering the second flat surface 614. Thus, the canted surfaces opposite the first flat surface 612 have a different set of refractive angles than the canted surfaces opposite the second flat surface 614 to focus all the light rays on a single focal point.

The bend 611 can form any appropriate angle. For example, the bend can form an angle that is less than 5 degrees, less than 10 degrees, less than 15 degrees, less than 20 degrees, less than 25 degrees, less than 30 degrees, less than 35 degrees, less than 40 degrees, less than 45 degrees, less than 55 degrees, less than 65 degrees, less than 75 degrees, less than 90 degrees, less than another appropriate degree, or combinations thereof.

While this embodiment is depicted with just first and second flat surfaces, any number of flat surfaces can be used in accordance with the principles described herein. For example, the light receiving surface can include a first bend and a second bend that causes the relative slope of the light receiving surface to get steeper and steeper.

FIG. 7 depicts an example of an alternative light concentrator apparatus 700. In this example, the light concentrator apparatus 700 includes concentrating lenses 702 that alternate with offset angles with respect to each other, as discussed above. In this example, each of the offset alternating lenses 702 directs light to offset focal points 704 on a light receiver 706.

The light receiver 706 can be a photovoltaic cell, clothes, a container, a building component, etc. However, as shown in FIG. 7, the light receiver 706 can be a pipe that forms a part of a pathway configured to accommodate a flow of fluid. The light receiver 706 can receive fluid, such as oil, water, a gas, or another type of fluid, from any appropriate source. The pathway can route the fluid through any appropriate pathway. In the illustrated example, a first portion 708 of the pathway is formed in the light receiver 706. A second portion 710 of the pathway is defined in part by the alternating concentrating lenses 702. The second portion 710 of the pathway can also be partially defined by a transparent material, collectively defining a fluid pathway.

The transparent material 712 and the concentrating lenses 702 can define a space that constitutes the second portion 710 of the pathway. A first valve 714 can control a flow of fluid entering the second portion 710 of the pathway, and a second valve 716 can control a flow of fluid exiting the second portion 710 of the pathway. The fluid pressure within the second portion 710 can be adequate to reduce unfilled space within the second portion 710 and can include exhaust ports (not shown) or other features intended to eliminate any bubbles or other impurities that can affect the efficiency of the light concentrator apparatus 700. Each optical boundary within the second portion 710 can cause at least a small amount of refraction. Further, refraction can occur when the surface of a liquid enters the second portion 710 of the pathway because the liquid's inertia from entering the second portion 710 can cause the surface angle to dynamically change. By controlling the fluid pressure within the second portion 710 so that no unfilled gaps are present, the number of optical boundaries and be reduced and their angles can be controlled and the liquid forms an integral part of the lens in the second portion 710.

The solar energy transmitted through the transparent material 712 can heat the fluid while the fluid is in the second portion 714 of the pathway. When the fluid reaches the first portion 708 of the pathway, the fluid's temperature can raise even more since the solar energy is concentrated on the light receiver 706. In this manner, the fluid can be heated in at least two stages.

While the examples above have been described with the canted surfaces being on the light exiting surface of the concentrating lens, in some examples, canted faces are incorporated into the light receiving surface. In these types of examples, the canted faces are incorporated into both the light receiving surface and the light exit surface. In other examples, the canted faces are just incorporated into the light receiving surface.

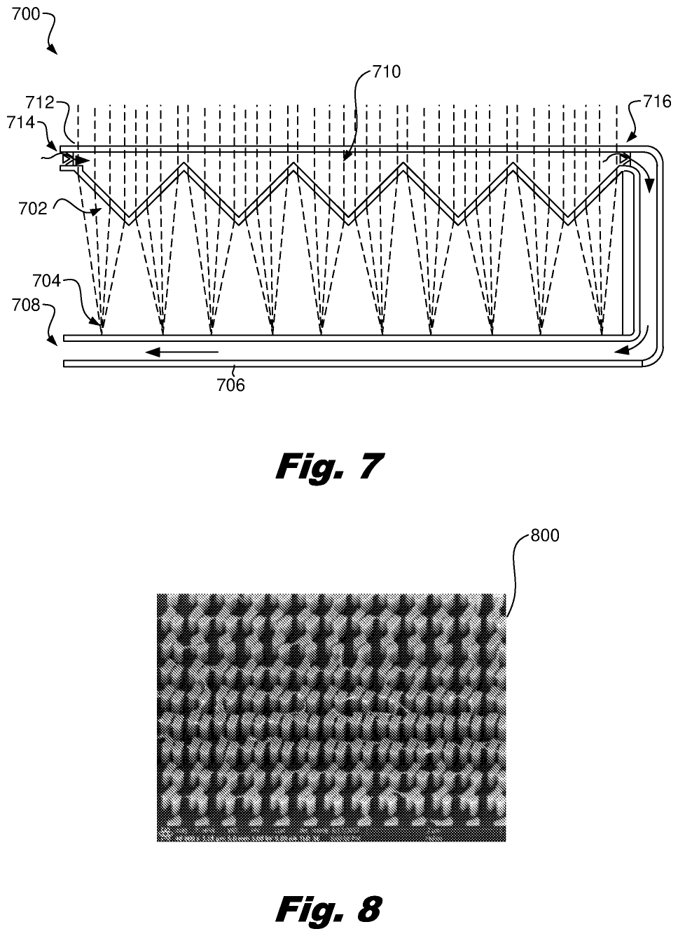

Alternatively, while the above examples have been described in the context of using angled refractive surfaces to controllably direct light through a lens onto a desired object, any number of light refractive or modifying geometries or surfaces can be used to predictably direct light received by a light receiving surface. According to one exemplary embodiment, meta-optics can be used to controllably direct light, according to the present exemplary system, either for use with a solar panel, for heating, or for other light focusing purposes. The meta-optics can include one or more ultrathin arrays of tiny waveguides, known as meta-surfaces, which bend at least visible light as it passes there through. FIG. 8 illustrates a scanning electron microscope image of exemplary meta-optics. As illustrated in FIG. 8, the meta-optics lens 800 can be formed to be a flat panel, either with or without the formation of a chamber for multiple stage heating, as described above. The waveguide meta-surfaces can be made of any number of materials that can strongly confine light with a high refractive index, including, but in no way limited to, titanium dioxide, a silver dioxide, or graphene. Additionally, the meta-surfaces can be formed and organized or tuned to selectively and precisely focus received light on a desired surface. The meta-surfaces can be formed using any number of additive or subtractive methods, including, but in no way limited to, patterning, dry or wet etching, electron beam lithography, and/or 3-D printing. Accordingly, compared to traditional lens systems, weight and thickness can be reduced while providing an increased efficiency.

While various uses and configurations of the present systems have been individually described above, each of the systems and configurations can be combined to create hybrid systems. For example, the fluid filled second portion 710 shown in FIG. 7 can be incorporated with a photovoltaic light receiver 706 in a single system. According to this system, a fluid can be heated in the fluid filled second portion 710, while efficiently transmitting and focusing light to the photovoltaic light receiver 706. Additionally, the described components can be combined in various configurations and sizes (from macro levels to micro scale) to be applied to any number of environments and targets, including, but in no way limited to, heating clothes, tents, buildings and building components, windows, vehicles, cooking appliances, heat pumps, sterilization systems, and any other thermal energy consuming systems.

Other examples and implementations are within the scope and spirit of the disclosure and appended claims. For example, features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C). Further, the term “exemplary” does not mean that the described example is preferred or better than other examples.

The foregoing description, for purposes of explanation, uses specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

1-6. (canceled)

7. A concentrator apparatus, comprising:
a light receiver;
a light concentrator, the light concentrator including a first concentrating lens with a first focal point on the light receiver;
wherein a first side of the first concentrating lens is closer to the first focal point than a second side of the first concentrating lens.

8. The concentrator apparatus of claim 7, further including a partial vacuum space between the light concentrator and the light receiver.

9. The concentrator apparatus of claim 7, wherein the light receiver includes an insulating section that is configured to retain heat within the light receiver.

10-12. (canceled)

13. The concentrator apparatus of claim 7, wherein the light receiver comprises a pipe.

14. The concentrator apparatus of claim 13, wherein the pipe is configured to carry a fluid.

15. The concentrator apparatus of claim 14, wherein the pipe comprises a vacuum section.

16. The concentrator apparatus of claim 13, wherein the pipe comprises an insulation layer configured to retain heat within the pipe.

17. The concentrator apparatus of claim 16, further comprising a heat exchanger incorporated into the insulation layer.

18. The concentrator apparatus of claim 7, further comprising a heat spreader incorporated into the light receiver.

19. The concentrator apparatus of claim 7, further comprising:
a second concentrating lens adjacent to the first concentrating lens;
wherein the first concentrating lens is offset from the second concentrating lens; and
wherein the second concentrating lens has a second focal point on the light receiver.

20. (canceled)

21. The concentrator apparatus of claim 19, wherein the first focal point and the second focal point are at a same location on the light receiver.

22-39. (canceled)

40. A concentrating lens, comprising:
a transparent material, the transparent material including:
a light receiving surface;
a light exiting surface opposite the light receiving surface;
an area between the light receiving surface and the light exiting surface defining at least one concentrating plane, the at least one concentrating plane including a midpoint;
a plurality of refractive surfaces incorporated into at least one of the light receiving surface and the light exiting surface;
wherein the plurality of refractive surfaces directs light passing through the transparent material to a collective focal point; and
wherein a focal axis from the collective focal point to the midpoint forms a non-right angle with the at least one concentrating plane.

41. The concentrating lens of claim 40, wherein the non-right angle is between 60 degrees and 89 degrees.

42. A concentrator apparatus, comprising:
a light receiver;
a light concentrator, the light concentrator including;
a first transparent material;
a first concentrating lens with a first focal point on the light receiver;
a second transparent material between the first transparent material and the first concentrating lens;
wherein the first concentrating lens is configured to direct light to the first focal point and is asymmetrically positioned over the first focal point.

43. The concentrator apparatus of claim 42, wherein the second transparent material comprises a fluid.

44. The concentrator apparatus of claim 42, further comprising a pathway defined in the light receiver configured to accommodate a flow of fluid.

45. The concentrator apparatus of claim 44, wherein the pathway further comprises:
a first portion defined in the light receiver; and
a second portion defined in part by the first transparent material and the first concentrating lens.

46. The concentrator apparatus of claim 45, wherein the second transparent material is configured to flow through the pathway.

47. The concentrator apparatus of claim 46, wherein said concentrator is configured to transfer solar heat to the second transparent material when the second transparent material is located in the first portion of the pathway; and
transfer solar heat to the second transparent material when the second transparent material is located in the second portion of the pathway;
wherein the first solar heat transfer exhibits a greater temperature increase than the second solar heat transfer.

48. The concentrating lens of claim 40, wherein the plurality of refractive surfaces each comprise a meta-optic array.
